(19) United States
(12) Patent Application Publication
(10) Pub. No.: US 2023/0002889 A1
(43) Pub. Date: Jan. 5, 2023

(54) CHEMICAL VAPOR DEPOSPITION FURNACE FOR DEPOSITING FILMS

(71) Applicant: ASM IP Holding B.V., Almere (NL)

(72) Inventors: Dieter Pierreux, Pepingen (BE); Werner Knaepen, Leuven (BE); Arjen Klaver, Neerijse (BE); Lucian Jdira, Nieuw Vennep (NL); Marina Mariano, Leuven (BE); Theodorus G.M. Oosterlaken, Oudewater (NL); Herbert Terhorst, Amersfoort (NL); Bert Jongbloed, Oud-Heverlee (BE); Subir Parui, Leuven (BE)

(21) Appl. No.: 17/850,141

(22) Filed: Jun. 27, 2022

Related U.S. Application Data
(60) Provisional application No. 63/216,639, filed on Jun. 30, 2021.

(51) Int. Cl. C23C 16/30; C23C 16/54; C23C 16/52

(52) U.S. Cl. CPC C23C 16/303; C23C 16/54; C23C 16/52

(57) ABSTRACT

A chemical vapor deposition furnace for depositing silicon nitride films, is discloses. The furnace comprising a process chamber elongated in a substantially vertical direction and a wafer boat for supporting a plurality of wafers in the process chamber. A process gas injector is provided inside the process chamber extending in a substantially vertical direction over substantially a wafer boat height and comprising a feed end connected to a source of a silicon precursor and a source of a nitrogen precursor and a plurality of vertically spaced gas injection holes to provide gas from the feed end to the process chamber. The furnace may comprise a purge gas injection system to provide a purge gas into the process chamber near a lower end of the process chamber.

### CROSS-REFERENCE TO RELATED APPLICATIONS

This application claims priority to U.S. Provisional Patent Application Ser. No. 63/216,639 filed Jun. 30, 2021 titled CHEMICAL VAPOR DEPOSITION FURNACE FOR DEPOSITING FILMS, the disclosure of which is hereby incorporated by reference in its entirety.

### FIELD OF THE INVENTION

The present invention relates to the field of semiconductor processing, and more in particular to a chemical vapor deposition furnace for depositing silicon nitride films.

### BACKGROUND

The simultaneous processing of a plurality of semiconductor wafers in a vertical batch furnace presents the problem of how to provide all wafers that are stacked into a wafer boat with substantially the same layer quality across the length of the wafer boat and across the wafer surface. To promote the uniformity of the quality of the layers, a vertical furnace is commonly equipped with a boat rotation mechanism that rotates the wafer boat during processing so as to average out non-uniformities across the wafers.

A process condition to optimize the uniformity of the layer thickness deposited on the wafers over the boat is temperature. To obtain uniform layer thickness across the substrates of a batch of wafers in a wafer boat, each of the wafers thereof may preferably be heated substantially uniformly to a carefully tuned temperature by heating means disposed proximate a side wall of the process chamber and proximate a top wall of the process chamber.

It has been found that by tuning the temperature over the boat the layer thickness uniformity over the boat may be improved but that the quality of the deposited layers over the boat may start to show variations. These variations may be unwanted.

### SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

It is an objective to provide for a chemical vapor deposition furnace whereby layer quality uniformity of the deposited layers over the wafer boat may be improved.

According to an embodiment there may be provided a chemical vapor deposition furnace for depositing silicon nitride films. The furnace may comprise a tube defining a process chamber elongated in a substantially vertical direction; and, a wafer boat for supporting a plurality of wafers in the process chamber. The furnace may have a process gas injector inside the process chamber extending in a substantially vertical direction over substantially a wafer boat height and comprising a feed end in use connected to a first source providing a silicon precursor and a second source providing a nitrogen precursor. The process gas injector may be provided with a plurality of vertically spaced gas injection holes to provide gas from the feed end to the process chamber. The furnace may have a purge gas injection system to provide a purge gas into the process chamber near a lower end of the process chamber.

According to a further embodiment there is provided a method for depositing silicon nitride layer on a wafer, comprising:

providing a plurality of wafers in a wafer boat and loading the wafer boat in a substantial vertical direction into a process chamber of a chemical vapor deposition furnace;

flowing a gas based on a silicon precursor and a nitrogen precursor into a process gas injector to a plurality of vertically spaced gas injection holes to provide the gas to the process chamber over the wafers in the wafer boat; and,

providing a purge gas into the process chamber near a lower end of the process chamber.

The various embodiments of the invention may be applied separate from each other or may be combined. Embodiments of the invention will be further elucidated in the detailed description with reference to some examples shown in the figures.

### BRIEF DESCRIPTION OF THE FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 shows a cross-sectional view of a tube of a vertical process furnace.

FIG. 2 discloses schematically a valve system, a purge gas injection system, and a control system for cooperation with the chemical vapor deposition furnace of FIG. 1.

### DETAILED DESCRIPTION OF THE FIGURES

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below. The illustrations presented herein are not meant to be actual views of any particular material, structure, or device, but are merely idealized representations that are used to describe embodiments of the disclosure.

As used herein, the term “substrate” or “wafer” may refer to any underlying material or materials that may be used, or upon which, a device, a circuit, or a film may be formed. The term “semiconductor device structure” may refer to any portion of a processed, or partially processed, semiconductor structure that is, includes, or defines at least a portion of an active or passive component of a semiconductor device to be formed on or in a semiconductor substrate.

Semiconductor substrates can be processed in batches in vertical furnaces. An example of such processing is the deposition of layers of various materials on the substrates. Some of the process may be based on chlorides and ammonia for example.

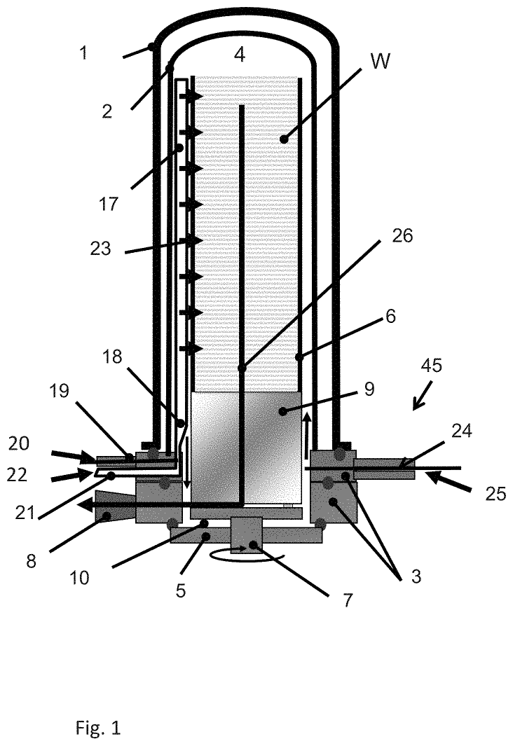

FIG. 1 is a cross sectional side view of an example of a chemical vapor deposition furnace, including a process tube 1 defining a process chamber 4. The furnace may comprise a vertically movable door 5 configured to close off a central inlet opening 10 in lower and/or upper flanges 3 and configured to support a wafer boat 6 that is configured to hold a plurality of substrates. The upper and lower flanges 3 may be partially closing an open end of the process tube 1. A liner 2 may extend along the process tube 1 to protect the tube.

The door 5 may be provided with a drive 7 to allow for rotation of the wafer boat 6 in the process chamber 4. In between the drive 7 and the wafer boat 6 a pedestal 9 may be provided. The pedestal 9 may be provided with heaters and/or thermal insulators to improve the heat uniformity for the wafers in the boat 6. The liner 2 may be closed at a higher end for example with a dome shape and may be substantially closed for gases above an opening at the bottom. The lower flanges 3 comprises an inlet opening 10 configured to insert and remove a boat 6 configured to carry a plurality of substrates in the process chamber 4.

A process gas injector 17 may be provided inside the process chamber 4 extending in a substantially vertical direction over substantially a height of the wafer boat 6. The liner 2 extending along the tube 1 may have a radially outwardly extending bulge to accommodate the process gas injector 17. The process gas injector 17 comprises a feed end 18 operationally connected to a first feed line 19 which may be connected to a first source of a silicon precursor 20. The feed end 18 may be operationally connected to a second feed line 21 which may be connected to a second source comprising a nitrogen precursor 22.

The silicon precursor provided at the feed end 18 of the process gas injector may comprise silane. The silicon precursor may comprise one or more compounds chosen from a group consisting of monochlorosilane, dichlorosilane, trichlorosilane, tetrachlorosilane, disilane and trisilane.

The nitrogen precursor provided at the feed end 18 of the process gas injector may comprise ammonia. The nitrogen precursor and the silicon precursor may start to mix and react with each other when they enter the process gas injector 17 at the feed end 18.

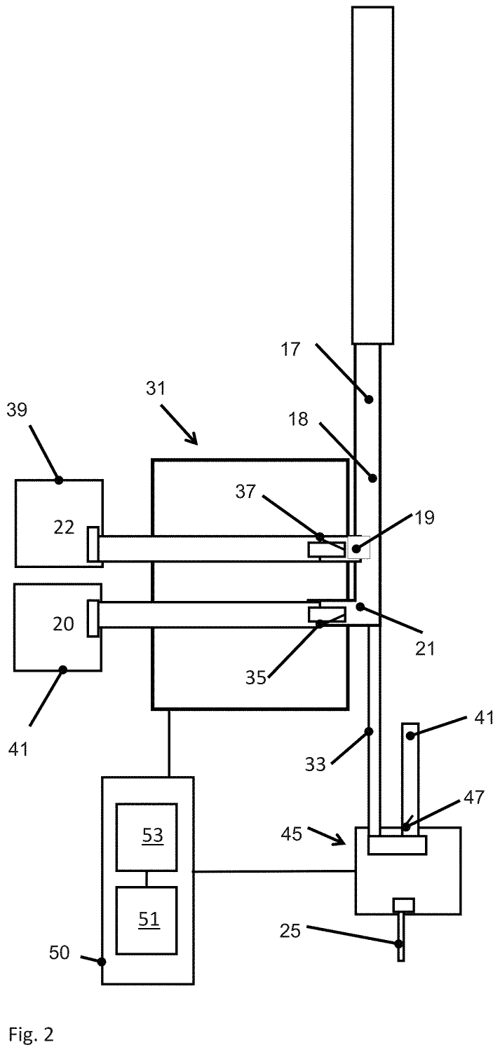

FIG. 2 discloses schematically a valve system 31 for cooperation with the chemical vapor deposition furnace of FIG. 1. FIG. 2 shows that the feed end 18 of the process gas injector 17 (only partially shown) may be connected to a second source 39 comprising a nitrogen precursor 22 via the first feed line 19 and a second valve 37. The feed end 18 of the process gas injector 17 may also being connected to a first source 41 comprising a silicon precursor 20 via the second feed line 21 and a second valve 35. If both the first and second valves 35, 37 are opened for silicon precursor 20 and nitrogen precursor 22 the feed end 18 of the process gas injector 17 will receive process gas for depositing silicon nitride layers in the process chamber 4. It may be understood that with a source is meant a vessel containing the precursor and/or gas or a connection of the fab providing the precursor and/or gas.

A controller 50 may be provided which is operably connected to the valve system 31. The controller 50 may control the first and second valve 35, 37 during deposition. The controller 50 may be provided with a memory 50 and a processor 53. The controller 50 may be provided with a clock, for example as part of the processor 53 to run a recipe as a function of time. The controller 50 may control the flow of process gas through the process gas injector 17 into the process chamber 4 to between 100 and 500, preferably 250 cubic centimeters per minute (SCCM).

Returning to FIG. 1, the process gas injector 17 may be provided with a plurality of vertically spaced gas injection holes 23 to provide gas received in the interior of the injector 17 at the feed end 18 to the process chamber 4 uniformly over the length of the wafer boat 6. The plurality of gas injection holes 23 may extend over a part of a height of the gas process gas injector 17. The first and second feed line 19, 21 may be provided partially as a passage through one of the flanges 3 and further as a tube to a source of the nitrogen precursor 22 or the silicon precursor 20.

The plurality of gas injection holes may extend over a part of a height of the process gas injector 17. The gas injection holes 23 each may have a gas injection hole diameter of at least about 1 mm. The diameter of the gas injection holes may for example be about 3 mm. All gas injection hole diameters of the process gas injector 17 may be substantially equal. Each gas injection hole may have a gas injection hole area, wherein an aggregate area of all the gas injection hole areas of the process gas injector 17 may be at least about 30 mm². The aggregate area of all the gas injection hole areas may be between about 200 mm² and 400 mm².

The chemical vapor deposition furnace may be provided with a purge gas injection system 45 constructed and arranged to provide a purge gas 25 into the process chamber 4 near a lower end of the process chamber 4. It has been found that by providing the flow of purge gas 25 into the process chamber 4 near a lower end of the process chamber the uniformity of quality of the silicon nitride depositions on the wafers over the height over the wafer boat 6 may be improved. The uniformity of the quality may be controlled by measuring the wet etch rate or the refractive Index from deposited layers on a plurality of wafers across the wafer boat 6. The plurality of gas injection holes 23 may extend over a part of a height of the process gas injector 17 and the purge gas injection system 45 may be constructed and arranged to provide the purge gas 24 below the lowest gas injection hole.

The tube 1 may be supported on a flange 3 with a central inlet opening 10 that is provided with a door 5 which may define an end of the processing chamber 4. The purge gas injection system 45 may be constructed and arranged to provide the purge gas 25 above the door 5. The purge gas injection system 45 may be constructed and arranged to provide the purge gas 25 at the height of the flange 3. The purge gas may be provided through a passage in the flange 3.

The chemical vapor deposition furnace may be provided with a gas exhaust opening 8 below the tube 1 and the purge gas injection system 45 may be constructed and arranged to provide the purge gas 25 at the height of the gas exhaust opening 8. The purge gas injection system may be constructed and arranged to provide the purge gas at a first side of the chemical vapor deposition furnace and the chemical vapor deposition furnace may be provided with the gas exhaust opening below the tube 1 at a second side of the chemical vapor deposition furnace unequal to the first side. In this way it may be circumvented that the purge gas 25 is immediately pumped away via the gas exhaust opening 8.

The purge gas injection system 45 may be constructed and arranged to provide a purge gas 25 into the process chamber 4 near the flange 3. A purge gas line 24 provided to the purge gas injection system 45 may therefore be provided partially as a passage through one of the flanges 3 and further as a tube to a source of the purge gas 25.

More details of the purge gas injection system 45 may be shown in FIG. 2. The purge injection gas system 45 may be constructed and arranged to provide an inert gas as a purge gas. The purge gas injection system 45 may be constructed and arranged to provide nitrogen as the inert purge gas. Nitrogen is a cheap inert gas which is readily available in a fab. It must be understood that the nitrogen precursor may not be nitrogen. The nitrogen precursor may be reactive while the nitrogen may not be reactive.

The purge gas injection system 45 may be provided with a purge valve 47 to control the flow of purge gas 25. The purge gas injection system 45 may be controlled by the controller 50. The purge gas injection system 45 may be controlled to provide between 15 to 100, preferably 30 to 70 and most preferably around 50 cubic centimeters per minute (SCCM) of purge gas into the process chamber 4. The purge injection gas system 45 may be constructed and arranged to provide an inert gas as a purge gas near a lower end of the processing chamber 4 to improve the uniformity of the quality of the silicon nitride depositions on the wafers over the height over the wafer boat 6. The purge valve 47 of the purge injection gas system 45 may be controlled by the controller 50 to adjust the flow of purge gas in the processing chamber to adjust the uniformity of the quality of the silicon nitride depositions on the wafers over a height over the wafer boat 6.

The purge gas injection system 45 may optionally be provided with a process gas injector shortcut 33 constructed and arranged to also provide silicon precursor and/or nitrogen precursor via the purge gas injection system 45 into the process chamber 4 at a lower end. The silicon precursor and/or nitrogen precursor may be mixed with purge gas 25.

The other way around, the process gas injector shortcut 33 may also be used to provide purge gas 25 into the process chamber 4 via the process gas injector 18. This purge gas may be mixed with silicon precursor and nitrogen precursor.

The chemical vapor deposition furnace may be provided with the gas exhaust opening 8 for removing gas at a lower end of the process chamber 4. In this way by closing the liner 2 above the liner opening for gases, providing a process gas with the process gas injector 17 and a purge gas 25 with the purge gas injection system to the process chamber 4 and removing gas from the process chamber 4 by the gas exhaust opening 8 at a lower end of the process chamber 4 a down flow 26 in the process chamber 4 may be created. This down flow may transport contamination of reaction byproducts, particles from the substrates, the boat 6, the liner 2 and/or the support area of the liner 2 on the flange 3 downward to the gas exhaust opening 8 away from the processed substrates W. The gas exhaust opening 8 for removing gas from the process chamber 4 may be operationally connected to a pump. The pump may be used to control the pressure in the process chamber 4 to a pressure between 20 and 500, more preferably between 50 to 300 and most preferably between 100 and 150 millitorr.

The chemical vapor deposition furnace may be used for depositing a silicon nitride layer on a wafer W by: providing a plurality of wafers in a wafer boat 6 and loading the wafer boat in a substantial vertical direction into a process chamber 4 of a chemical vapor deposition furnace; flowing a process gas based on a silicon precursor 20 and a nitrogen precursor 22 into a process gas injector 17 to a plurality of vertically spaced gas injection holes 23 to provide the process gas to the process chamber 4 and over the wafers in the wafer boat; and, simultaneously providing a purge gas 25 into the process chamber 4 near a lower end of the process chamber 4. The method may comprises measuring the uniformity of the silicon nitride depositions on the wafers over a height over the wafer boat 6; and adjusting the flow of a purge gas 25 into the process chamber 4 near a lower end of the process chamber to improve the uniformity of quality of the silicon nitride depositions on the wafers over a height over the wafer boat. The pressure in the process chamber may be controlled to a pressure between 20 and 500, more preferably between 50 to 300 and most preferably between 100 and 150 millitorr.

The chemical vapor deposition furnace may be provided with a heater to heat the wafers in the wafer boat 6. The chemical vapor deposition furnace may be provided with a temperature measurement system mounted on the flange 3 and extending along an outer surface of the liner 2 towards the top end of the liner to measure a temperature. The temperature measurement system may comprise a beam with a plurality of temperature sensors provided along the length of the beam to measure the temperature at different heights. The measured temperature may be used to control the heater.

The preferred embodiments may be applicable to chemistries wherein a chlorine precursor is used in combination with ammonia (NH₃) as the nitrogen precursor. Examples of chlorine precursors are: TiCl₄, SiCl₂H₂, HfCl₄ and AlCl₃.

Although illustrative embodiments of the present invention have been described above, in part with reference to the accompanying drawings, it is to be understood that the invention is not limited to these embodiments. Variations to the disclosed embodiments can be understood and effected by those skilled in the art in practicing the claimed invention, from a study of the drawings, the disclosure, and the appended claims.

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, it is noted that particular features, structures, or characteristics of one or more embodiments may be combined in any suitable manner to form new, not explicitly described embodiments.

1. A chemical vapor deposition furnace for depositing silicon nitride films, comprising:
a tube defining a process chamber elongated in a substantially vertical direction;
a wafer boat for supporting a plurality of wafers in the process chamber; and
a process gas injector inside the process chamber extending in a substantially vertical direction over substantially a wafer boat height and comprising a feed end in use connected to a first source providing a silicon precursor and a second source providing a nitrogen precursor and a plurality of vertically spaced gas injection holes to provide gas from the feed end to the process chamber; wherein the furnace comprises:
a purge gas injection system to provide a purge gas into the process chamber near a lower end of the process chamber.

2. The chemical vapor deposition furnace of claim 1, wherein the plurality of gas injection holes extend over a part of a height of the process gas injector and the purge gas injection system is constructed and arranged to provide the purge gas below the lowest gas injection hole.

3. The chemical vapor deposition furnace of claim 1, wherein the tube is supported on a flange with a central inlet opening that is provided with a door and the purge gas injection system is constructed and arranged to provide the purge gas above the door.

4. The chemical vapor deposition furnace of claim 1, wherein the tube is supported on a flange and the purge gas injection system is constructed and arranged to provide the purge gas at substantially the same height as the flange.

5. The chemical vapor deposition furnace of claim 1, wherein the tube is supported on a flange and the purge gas injection system is constructed and arranged to provide the purge gas through a passage in the flange.

6. The chemical vapor deposition furnace of claim 1, wherein the chemical vapor deposition furnace is provided with a gas exhaust opening below the tube and the purge gas injection system is constructed and arranged to provide the purge gas at substantially the same height as the gas exhaust opening.

7. The chemical vapor deposition furnace of claim 1, wherein the purge gas injection system is constructed and arranged to provide the purge gas at a first side of the chemical vapor deposition furnace and the chemical vapor deposition furnace is provided with a gas exhaust opening below the tube at a second side of the chemical vapor deposition furnace unequal to the first side.

8. The chemical vapor deposition furnace of claim 1, wherein the purge gas injection system is connected to a purge gas source.

9. The chemical vapor deposition furnace of claim 8, wherein the purge injection gas system is constructed and arranged to provide an inert gas as a purge gas.

10. The chemical vapor deposition furnace of claim 9, wherein the purge gas injection system is constructed and arranged to provide nitrogen as the inert purge gas.

11. The chemical vapor deposition furnace of claim 1, wherein the purge gas injection system is constructed and arranged to provide between 15 to 100 cubic centimeters per minute (SCCM) of purge gas into the process chamber.

12. The chemical vapor deposition furnace of claim 11, wherein the purge gas injection system is constructed and arranged to provide between 30 to 70 cubic centimeters per minute (SCCM) of purge gas into the process chamber.

13. The chemical vapor deposition furnace of claim 1, wherein the purge gas injection system is constructed and arranged to provide also silicon precursor and nitrogen precursor into the process chamber near a lower end of the process chamber.

14. The chemical vapor deposition furnace of claim 8, wherein the purge injection gas system is constructed and arranged to provide an inert gas as a purge gas in the processing chamber to improve the uniformity of the silicon nitride depositions on the wafers over a height over the boat.

15. The chemical vapor deposition furnace of claim 1, wherein the first source comprises silane as the silicon precursor.

16. The chemical vapor deposition furnace of claim 1, wherein the first source comprises one or more compounds chosen from a group consisting of monochlorosilane, dichlorosilane, trichlorosilane, tetrachlorosilane, disilane and trisilane as the silicon precursor.

17. The chemical vapor deposition furnace of claim 1, wherein the second source comprises ammonia as the nitrogen precursor.

18. The chemical vapor deposition furnace of claim 1, wherein the flow of gas through the process gas injector into the process chamber is between 100 and 1000, preferably 250 cubic centimeters per minute (SCCM).

19. A method for depositing a silicon nitride layer on a wafer, comprising:
providing a plurality of wafers in a wafer boat and loading the wafer boat in a substantial vertical direction into a process chamber of a chemical vapor deposition furnace;
flowing a gas based on a silicon precursor and a nitrogen precursor into a process gas injector to a plurality of vertically spaced gas injection holes to provide the gas to the process chamber over the wafers in the wafer boat; and,
providing a purge gas into the process chamber near a lower end of the process chamber.

20. The method for depositing a silicon nitride layer on a wafer according to claim 19, wherein the method comprises:
measuring the uniformity of the silicon nitride depositions on the wafers over a height over the wafer boat; and
adjusting the flow of a purge gas into the process chamber near a lower end of the process chamber to improve the uniformity of the silicon nitride depositions on the wafers over a height over the wafer boat.

21. The method for depositing a silicon nitride layer on a wafer according to claim 19, wherein the method comprises:
controlling the pressure in the process chamber to a pressure between 20 and 500, more preferably between 50 to 300 and most preferably between 100 and 150 milliTorr.
